(19) United States
(12) Patent Application Publication
(10) Pub. No.: US 2013/0277669 A1
(43) Pub. Date: Oct. 24, 2013

(54) ELECTRON TRANSPORT LAYER

(71) Applicants: Frederik Christian Krebs, Lyngby (DK); Roar Søndergard, Bronshoj (DK); Kion Norrman, Frederiksberg (DK); Mikkel Jorgensen, Glostrup (DK)

(72) Inventors: Frederik Christian Krebs, Lyngby (DK); Roar Søndergard, Bronshoj (DK); Kion Norrman, Frederiksberg (DK); Mikkel Jorgensen, Glostrup (DK)

(73) Assignee: The Technical University of Denmark, Kgs. Lyngby (DK)

(21) Appl. No.: 13/825,536

(22) PCT Filed: Sep. 27, 2011
(86) PCT No.: PCT/EP11/66761

§ 371 Date: Jul. 9, 2013

(30) Foreign Application Priority Data
Sep. 27, 2010 (GB) 1016216.2
Sep. 30, 2010 (GB) 1016472.1

(51) Int. Cl. H01L 51/00; H01L 51/50; H01L 51/42

(52) U.S. Cl. CPC H01L 51/0022; H01L 51/4213; H01L 51/5072
USPC 257/43; 438/82; 438/47; 252/519.5; 252/519.3; 427/126.3

(57) ABSTRACT

The present invention provides: a method of preparing a coating ink for forming a zinc oxide electron transport layer, comprising mixing zinc acetate and a wetting agent in water or methanol; a coating ink comprising zinc acetate and a wetting agent in aqueous solution or methanolic solution; a method of preparing a zinc oxide electron transporting layer, which method comprises: i) coating a substrate with the coating ink of the present invention to form a film; ii) drying the film; and iii) heating the dry film to convert the zinc acetate substantially to ZnO; a method of preparing an organic photovoltaic device or an organic LED having a zinc oxide electron transport layer, the method comprising, in this order: a) providing a substrate bearing a first electrode layer; b) forming an electron transport layer according to the following method: i) coating a coating ink comprising an ink according to the present invention to form a film; ii) drying the film; iii) heating the dry film such that the zinc acetate is substantially converted to ZnO; c) forming an active layer; d) forming a hole transport layer; and e) forming a second electrode layer; and an optoelectronic device comprising an electron transporting layer comprising zinc oxide and a wetting agent.

The present invention relates to a method of formation of a zinc oxide electron transport layer, an ink for use in that method and a method of making the ink. Further, the present invention provides a method of forming a photovoltaic device incorporating the zinc oxide electron transport layer of the invention.

Electron transport layers are widely used in optoelectronic devices, such as photovoltaic devices and LEDs.

It has been found in prior art devices, in particular in organic photovoltaic devices with a zinc oxide electron transport layer, that the efficiency of the device is reduced by the presence of an inflection point in the I-V curve. In other words, the I-V curve for the device has an S-shape rather than the usual J-shape. This results in a reduction in fill factor FF (the ratio of maximum power to the external short circuit and open circuit values), short circuit current I_{SC} (the current measured when no voltage is applied to the cell) and the open circuit voltage V_{oc} (the voltage measured when no current flows). A typical I-V curve and an I-V curve with an inflection point are shown in FIG. 1. A diagram illustrating I_{SC}, V_{OC} and the maximum power of the device Pₘₐₓ is shown in FIG. 2.

Previous studies have found that with organic photovoltaic devices having ZnO nanoparticle electron transport layers, an inflection point is observed for the device when it is illuminated, which inflection point gradually is removed over continuous illumination conditions and/or on heating to give the usual J-shaped I-V curve. However, leaving the device in the dark for a period of time causes the inflection point to return, and, although a further period of illumination and/or heating will give a J-shaped I-V curve once again, the efficiency of the device will not be so high as that resulting from the first illumination and/or heating treatment. This is not acceptable in a device intended for commercialisation as the consumer is not willing to accept the need to light and/or heat treat a device prior to each period of use in order to obtain the maximum efficiency from it.

It has been concluded from studies of such devices that the nature of the zinc oxide layer has an important role in the appearance of the inflection point in the I-V curve. Possible processes causing this may be ZnO promoting photo-oxidation of organic compounds and UV induced desorption of oxygen from the ZnO surface. It is speculated that the re-appearance of the inflection point when the device is not illuminated may be caused by redistribution of oxygen within the device and chemical adsorption of oxygen from the surrounding atmosphere.

Accordingly, an aim of the present invention is to provide an improved zinc oxide electron transport layer for an optoelectronic device, which results in a device in which no inflection point is observed.

In order to increase the stability of such optoelectronic devices it is advantageous that the zinc oxide layer should adhere strongly to the underlying layer or layers in order to prevent defects forming in the device by peeling of the zinc oxide layer from the underlying layer or layers.

Accordingly, it is a further aim of the present invention that the methods and inks herein allow the production of a zinc oxide layer having improved adherence to underlying layers compared with prior art zinc oxide layers.

Environmental considerations are of increasing importance when devising processes for industrial scale use. Avoiding the use of organic solvents, which may be toxic and/or flammable and create disposal problems, is advantageous both in terms of reducing harm to the environment and reduction of cost. Accordingly, it is a further aim of the present invention to use aqueous solvents for the processing of the zinc oxide layers, and where possible for other layers in a photovoltaic device.

In order to facilitate mass production of devices such as solar cells, and particularly to minimise the cost of their production, it would be advantageous to use methods and inks suitable for processing in a roll-to roll process or other large scale printing process in which large numbers of devices can be printed at the same time. Accordingly, it is an aim of the present invention to provide methods and inks suitable for use in large scale printing processes.

In a first aspect, the present invention provides a method of preparing a coating ink for forming a zinc oxide electron transport layer, comprising mixing zinc acetate and a wetting agent in water or methanol.

Preferably, in accordance with one of the aims of the invention, the ink is made with water. The toxicity of methanol makes this solvent unsuitable for use on a commercial scale.

Preferably, the zinc acetate is used in the form Zn(OAc)₂.2H₂O.

A wetting agent is equivalent to a surfactant and is an agent that reduces the surface tension of a liquid or a solution to which it is added, and is usually an amphiphilic organic compound. Preferably, the wetting agent is non-ionic. Preferably, the wetting agent comprises a fluorocorbon chain, or is a polyethyleneglycol-alkylphenol ether such as Triton-X-100 or Nonoxynol-9. Preferably, the wetting agent is Zonyl®FSO-100 (2-(perfluoroalkyl)ethanol, CAS No 65545-80-4) or Triton® X-100 (polyethylene glycol p-(1,1,3,3-tetramethylbutyl)-phenyl ether, CAS No 9002-93-1). Most preferably, it is Zonyl® FSO-100 (2-(perfluoroalkyl)ethanol, CAS No 65545-80-4), as use of this wetting agent results in an inflection point free ZnO layer being formed with a significantly lower amount of the wetting agent present in the ink compared with that required for Triton® X-100.

It is of course preferable to use the minimum possible quantity of any additive to a functional layer as it is possible that additives can interfere with the function and/or stability of the layer and/or with the reaction of zinc acetate to form zinc oxide. For this reason, it has previously been preferred to achieve good wetting of the underlying layer with a coating ink by means of surface treatment of the underlying layer (eg by corona or plasma treatment) or by wetting it with a solvent found also in the coating ink prior to coating with the ink, rather than by including a wetting agent in the ink.

A suitable level of wetting agent in the ink is between 0.5 and 7.5 wt % of Zonyl® FSO-100 compared with Zn(OAc)₂.2H₂O, or between 0.5 and 25 wt % of Triton® X-100 compared with Zn(OAc)₂.2H₂O.

In view of the aim of including as small an amount of any additive as possible in the coating ink, it is preferred to use Zonyl® FSO-100 in an amount of 1 to 3 wt % compared with Zn(OAc)₂.2H₂O, and to use Triton® X-100 in an amount of 2 to 20 wt %, such as 5 to 15 wt %, or 7 to 12 wt %, preferably 9 wt % compared to Zn(OAc)₂.2H₂O. Typically, around 200 ml solvent (water or methanol) is used per 20 g Zn(OAc)₂.2H₂O.

Preferably, the method further comprises mixing AlOH(OAc)₂ into the ink and subsequently filtering out solids. The inclusion of the aluminium salt results in improved adhesion of the zinc oxide layer to the underlying device layers.

AlOH(OAc)₂ is also known as basic aluminium acetate and has the CAS No 142-03-0. Suitably, the AlOH(OAc)₂ is added in an amount of between 0.5 and 6 wt % compared with Zn(OAc)₂.2H₂O. Preferably, an amount of 1 to 1.5 wt % is used. It is found that in methanol 1 wt % is preferred, whereas in water 1.5 wt % is preferred.

It is essential to filter the ink when using AlOH(OAc)₂, as this substance is unstable, decomposing to Al₂O₃, which is insoluble in water or methanol. These insoluble salts must be filtered out before using the ink.

Most preferably, the ink has a composition of Zn(OAc)₂.2H₂O (0.1 gml⁻¹ in water), AlOH(OAc)₂ (1.5 wt % compared with Zn(OAc)₂.2H₂O) and Zonyl® FSO-100 (1-3 wt % compared with Zn(OAc)₂.2H₂O). This provides an ink that can be coated evenly on to the underlying layers, and produces a zinc oxide layer that is well adhered to the underlying layers and does not have an inflection point when incorporated into a photovoltaic device.

In a second aspect, the present invention provides a coating ink comprising zinc acetate and a wetting agent in aqueous solution or methanolic solution.

Preferred aspects of the first invention apply to the second aspect of the invention.

In a third aspect, the present invention provides a method of preparing a zinc oxide electron transporting layer, which method comprises:

i) coating a substrate with the coating ink of the second aspect of the invention to form a film;
ii) drying the film;
iii) heating the dry film to convert the zinc acetate substantially to ZnO.

The heating step iii) is essential for the layer to function as an electron transport layer, and is carried out until the zinc acetate is converted substantially to zinc oxide. The conversion can be detected using XPS or X-ray diffraction, but is most practically detected by a slight colour change in the film caused by a change in film thickness. For example, in the examples given herein, the film, though essentially colourless, has a yellow-green cast or sheen (similar to that produced by the coating of antireflective-coated eyeglass lenses) before heating, and a bluish-brown cast or sheen after the heating step is complete. Preferably, the heating step iii) is carried out at 140° C. for at least 5 min. Preferably the heating is carried out in the presence of humidity. More preferably, the heating step iii) is carried out for between 5 and 40 minutes, and most preferably for 10 minutes or longer. These conditions are found to be particularly practical for use in a large scale printing process such as a roll to roll process, where a flexible plastics substrate such as PET is used, which can withstand heating to 140° C. However, where a more heat-stable support is used, the heating can be carried out at higher temperatures and thus for a shorter period of time.

Preferred aspects of the first aspect of the invention apply also to the third aspect of the invention.

Preferably, the substrate on which the ZnO layer is formed is a substrate having a high surface energy. This is because water (and aqueous solutions generally) have a very high surface tension, and so wetting of a surface with water or an aqueous solution is difficult unless that surface has a high surface energy. A “high surface energy” may be quantified as a surface energy of at least 40-75 mN m⁻¹. Such substrates include glass, PET (having a surface energy of around 47 mN m⁻¹) or an ITO layer on a support (typically having a surface energy of around 35-45 mN m⁻¹). The surface energy of low energy substrates such as polyethylene (having a surface energy of around 20 mN m⁻¹), or of other substrates having an insufficiently high surface energy can be increased by means of surface treatments such as UV-ozone treatment, oxygen plasma treatment or corona treatment. For example, the surface energy of ITO on a support can be increased to as much as 75 mN m⁻¹ by such treatments. This increases the wettability of the surface of the ITO with water or an aqueous solution.

In a fourth aspect, the present invention provides a method of preparing an organic photovoltaic device or an organic LED having a zinc oxide electron transport layer, the method comprising, in this order:

a) providing a substrate bearing a first electrode layer;
b) forming an electron transport layer according to the following method:
i) coating a coating ink comprising zinc acetate and a wetting agent in aqueous solution or methanolic solution to form a film;
ii) drying the film;
iii) heating the dry film such that the zinc acetate is substantially converted to ZnO;
c) forming an active layer;
d) forming a hole transport layer; and
e) forming a second electrode layer.

It is found that such a device does not exhibit an inflection point in the I-V curve as has been found for prior art devices having a zinc oxide electron transport layer. The device therefore does not require treatment by heat or light prior to use in order to work efficiently.

It is not at present clear to the inventors why these particular compositions of ink used to coat the electron transport layer of the invention should result in improved performance.

Once again, preferred aspects of the first aspect of the invention apply also to the fourth aspect of the invention. Preferred aspects of the method of the third aspect of the invention also apply to the fourth aspect of the invention.

Preferably, the device is an organic photovoltaic device.

Suitably, the method may comprise the performance of the group of three steps (b), (c) and (d) more than once after step (a) and before step (e). Each time the group of steps (b), (c) and (d) is performed, a different selection of components of the active layer may be made. Suitably, the selection of the components of the active layer may alternate between two choices between each performance of each group of steps (b), (c) and (d). Cells constructed in this fashion are known as tandem cells.

The advantage of tandem cells is that they may harvest more light than a single cell. Suitably, two polymers harvesting light at different wavelength ranges may be employed in the active layer of each cell forming the tandem cell. For example, poly(3-carboxydithiophene) (P3CT) may be used as the hole conducting polymer in one cell and poly(carboxyterthiophene-co-diphenylthienopyrazine) (P3CTTP) as the hole conducting polymer in the adjacent cell. In this case P3CT harvests light up to around 600 nm and passes all light at longer wavelengths. The P3CTTP harvests light up to about 950 nm. In principle, such cells will have a higher efficiency for this reason. In order to maximise the energy obtained, the current generated by each cell must be matched since the cells are placed in series.

Suitable substrates include glass, plastics and cloth. It is necessary for at least one of the electrodes to be substantially transparent, to allow light to reach the active layer. This gives high cell efficiency. Where the first electrode layer is transparent, it is necessary also for the substrate to be substantially transparent. However, where the second electrode layer is to be transparent, the substrate and/or first electrode layer need not be transparent, although one or both may be transparent.

Preferably, the substrate is flexible, in order that roll-to-roll processing can be used. Suitable flexible substrates are fabrics, and plastics such as polyethylene terephthalate (PET), polyethylene ternaphthalate (PEN), poly(4,4′-oxydiphenylene-pyromellitimide) (Kapton®), or polylactic acid (PLA). Preferred polymers may be selected according to their properties such as their heat resistance, their flexibility, and their transparency, in order that they are as suited as possible to the type of photovoltaic device to be manufactured and the apparatus and process conditions to be used.

Preferably, the first electrode comprises a highly conductive layer that may distribute charge over the whole of its surface.

Preferably, the first electrode layer comprises ITO. Suitably, the first electrode layer may consist of ITO. However, other alternatives to ITO known in the art may also be used, such as fluorine tin oxide (FTC), a high conductivity organic polymer such as PEDOT:PSS or a metal grid-high conductivity organic polymer composite, or materials such as gold, silver, aluminium, calcium, platinum, graphite, gold-aluminium bilayer, silver-aluminium bilayer, platinum-aluminium bilayer, graphite-aluminium bilayer, and calcium-silver bilayer, tin oxide-antimony, using methods known in the art, such as application of a solution of a salt of the required electrode material. For example, Pode et al. (Applied Physics Letters, 2004, 84, 4614-4616) describes a method of forming a transparent calcium-silver bilayer electrode; Hatton et al. (Journal of Materials Chemistry, 2003, 13, 722-726) describes a method of producing a transparent gold electrode; Neudeck and Kress (Journal of Electroanalytical Chemistry, 1997, 437, 141-156) describe the formation of laminated gold micro-meshes for use as transparent electrodes. The transparent electrode layer may be formed by application of a solution of a salt of the selected metal. For example, a platinum electrode layer is formed by application of a freshly-made solution (5×10⁻³ M) of H₂PtCl₆ in isopropanol using an air-brush.

Of the non-ITO electrodes, a preferred transparent electrode layer may be formed as a silver grid under a PEDOT:PSS layer, as described by Aernouts et al. (Thin Solid Films 22 (2004) pp 451-452). Alternatively, an aluminium grid with a PEDOT:PSS overlayer or a screen printed silver grid with a screen printed PEDOT:PSS overlayer may be used (see below). Such methods of producing the transparent electrode layer may avoid the use of vacuum processing steps, which are slow and therefore expensive, and are not compatible with large scale printing processes, and the use of expensive ITO. However, it can be difficult to print a silver grid that is flat enough to ensure facile processing of subsequent layers. It may therefore be preferable in this case to adopt a non-transparent first electrode layer and a transparent second electrode layer (which is the silver grid), as described in Krebs (Organic Electronics, 2009, 10, 761-768).

The active layer may be any active layer known for use in an organic or polymer photovoltaic device. For example it may comprise a bulk heterojunction layer such as a combination of a light harvesting polymer and transition metal oxide, preferably ZnO, nanoparticles, as described in WO2009/103706, WO2009/103705, and Krebs et al., Solar Energy Materials and Solar Cells 2009, 93, 422-441. Alternatively, it may comprise a light harvesting polymer and a fullerene, as is well known in the art (see for examples Krebs and Norrman, Applied Materials and Interfaces 2010, 2, 877-887; Krebs, Organic Electronics 2009, 10, 761-768; Krebs, Solar Energy Materials and Solar Cells 2009, 93, 1636-1641; Krebs et al., Journal of Materials Chemistry 2009, 19, 5442-5451; and Günes et al., Chem. Rev. 2007, 107, 1324-1338).

Suitably, step c) is carried out by applying a coating ink comprising a light-harvesting polymer and an electron acceptor such as a fullerene or one or more transition metal oxides to the electron transport layer, and drying the coating ink layer. This method is applicable where the desired light harvesting polymer is soluble in conventional solvents. Examples of such light harvesting polymers are polythiophene derivatives or polyphenylenevinylene derivatives. In most cases, these are not soluble in water, and so an organic solvent must be used to prepare the active layer. For example, if poly-3-hexylthiophene (P3HT) is used, the solvent used to coat the active layer is suitably chlorobenzene, xylene or toluene. As an alternative, particularly considering the desire to eliminate the use of large quantities of organic solvents that present problems such as flammability, toxicity and disposal difficulties, water soluble light harvesting polymers such as polythiophene derivatives substituted with side chains giving the polymer water solubility may be used. Several water soluble polythiophene derivatives with sulfonic acid-terminated side chains are available commercially, and may be used in the present invention. Also, polymers containing free carboxylic acid groups may be used in the form of their ammonium salts (they are not soluble in water as the carboxylic acid), such as poly(3-carboxydithiophene) (P3CT) and poly(carboxyterthiophene-co-diphenylthienopyrazine)(P3CTTP).

However, the use of soluble light harvesting polymers in the active layer can cause problems when applying one or more further layers to the device, as the active layer can be dissolved by or interact with the solution used for coating the further layer or layers. For this reason, it is preferred to carry out step c) by applying a coating ink comprising a soluble precursor of a light harvesting polymer, an electron acceptor such as a fullerene or at least one transition metal oxide, and a solvent to the electron transport layer, drying the coating ink layer, and treating the dried coating ink layer to convert the soluble precursor into a light harvesting polymer that is substantially insoluble in the solvent of the coating ink.

The treatment of the soluble precursor to convert it into a light harvesting polymer that is substantially insoluble in the solvent used in the coating ink can preferably be achieved by thermal cleavage of a side chain such as an ester or a thioester, which undergo thermal cleavage of the (thio)ester group to leave a (thio)acid, or at higher temperatures can also eliminate the (thio)acid group completely resulting in the unsubstituted polymer. A typical scheme is shown below, and examples of such precursors are disclosed in WO2009/103706.

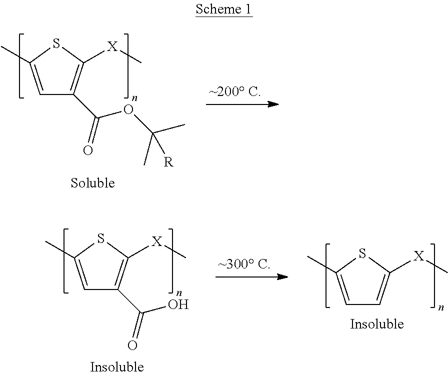

An advantage of using esters as the precursors is that after thermal cleavage the light harvesting polymer contains carboxylic acid groups capable of strong, non-covalent interactions so that the light harvesting polymer forms a hard insoluble matrix. Further, besides the processing advantages of solubility switching, removal of the side chains from the bulk of the active layer furthermore means removal of non-absorbing material, and several studies show enhanced stability of the active layer towards general degradation.

In a preferred embodiment, the precursor of the light harvesting polymer is a polythiophene (PT), or co-polymers of thiophene with, for example, benzothiadiazoles, thienopyrazines, dithienothiophenes or thienothiophenes, substituted with ester groups (C═O—O—R) which cleave to give free carboxylic acid groups.

However, it is in accordance with an aim of the present invention that all of the device layers should be processed from aqueous solution. Thus, it is preferred to use water soluble polythiophene derivatives in which the side chain giving the water solubility to the polythiophene is thermally cleavable from the polythiophene backbone. The polythiophene derivatives include co-polymers of thiophene with, for example, benzothiadiazoles, thienopyrazines, dithienothiophenes or thienothiophenes. The thermocleavability makes it possible to remove the side chains after processing of the active layer, rendering it insoluble, and thus allowing for subsequent aqueous processing without destroying the active layer. As previously mentioned the use of ionic moieties such as sulfonic acid salts on the side chains enhances the solubility towards aqueous media. However, the presence of the sulfonic acid groups on the side chains renders it impossible to remove the cleaved side chains from the active layer by evaporation after cleavage. Thus, besides the tertiary ester moiety, the side chain should consist of a polyether with one or more free alcohols in order to promote solubility towards aqueous media.

A preferred precursor to a light harvesting polymer is shown as Compound 1 below, which, when heated to around 200° C., undergoes rapid cleavage of the ester side chain to give the free carboxylic acid, and, when heated to around 300° C., undergoes rapid cleavage of both the ester side chain and the carboxylic acid group to give polythiophene, as illustrated generally in Scheme 1. The cleavage reactions can be carried out at lower temperatures, such as 140° C., but the heating must be continued for a much longer time in order for complete thermocleavage to take place, such as 5 h at 140° C. for thermocleavage of the ester to the carboxylic acid. It is not possible to conduct thermocleavage to remove the carboxylic acid group at 140° C. within a reasonable timescale.

It is of course possible to use many different heating means (eg hot air ovens, hotplates, horizontal or vertical ovens for passage of a web therethrough), and is also possible to use different film thicknesses for the coating of the ink for the active layer. This means of course that there can be some variation in the ideal conditions for thermocleavage of the ink layer depending on the apparatus and parameters used. These can be determined by the skilled person with trivial experimentation. The degree of thermocleavage of the ink layer can be determined by TOF-SIMS or by XPS, which allows one to distinguish between the presence of an ester group and a carboxylic acid group. On a more practical level, it is essential for the processing of subsequent layers that the ink layer is made insoluble by the thermocleavage conditions, which may be determined by rubbing the thermocleaved ink layer with a cotton bud wetted in the relevant solvent (eg, water where the next layer is to be processed in aqueous solution). When the layer has not been made sufficiently insoluble, the cotton bud will be coloured by the ink layer. It is generally found that 20 min heating at 140° C. is the minimum time required to make the ink layer sufficiently insoluble to process subsequent layers. At this stage the thermocleavage reaction to the carboxylic acid is not complete. For improved device performance it is preferred to heat the ink layer for longer so that a greater degree of conversion of the polymer in the ink to the carboxylic acid takes place, such as for 40 min, more preferably for around 2 h (at which time it is estimated that the conversion is around 90% complete), and most preferably for around 4 h (at which time it is estimated that the conversion to carboxylic acid is complete).

The synthesis and cleavage of this polymer is described in the Examples below.

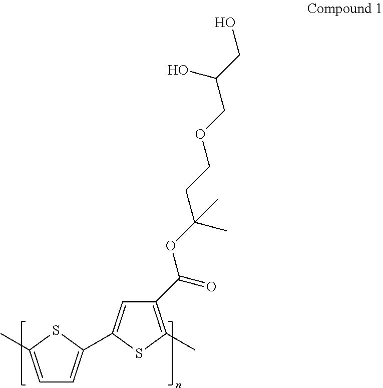

As the solubilising chain is removed during thermocleavage and film processing, it does not influence device performance at a later stage. The organisation of the molecules in the final film may show some dependence on the solubilising group.

The conditions used for the cleavage of the side chains are preferably compatible with the use of a large scale printing process, such as a roll to roll printing process. The methods and conditions set out in WO2009/103706 and in WO2009/103705 may suitably be used. Suitably, heating of the active layer is carried out at a temperature between 50 and 400° C., more preferably between 100 and 300° C., for example at a temperature of 210° C. The temperature must not be too high because at high temperatures the polymer and/or electrode material may start to degrade. Thus, for example, when using a PET substrate, this should not be heated to above 140° C. Also, the temperature should be chosen with reference to the chosen starting material and the product to be obtained on thermocleavage.

Alternatively, the heating may be carried out using a laser or other high powered light source in the wavelength range 475-532 nm in order that the active layer is heated without overheating of the underlying layers and the substrate.

More generally, light harvesting polymers used in the method of the fourth aspect of the invention may be further substituted to alter their electronic properties with electron withdrawing or donating groups, or to alter their physical properties. A mixture of substituents may be used. Preferably, the light harvesting polymer is unbranched. In certain cases it may be preferred to use a regioregular polymer rather than a regiorandom polymer.

The fullerene used in the active layer may suitably be any fullerene known in the art for use in the active layers of photovoltaic devices, such as a fullerene selected from the group consisting of phenyl-C61-butyric acid methyl ester (PCBM), phenyl-C71-butyric acid methyl ester (P70BM), BisP60BM, which is a mixture of regioisomers of the bis-cyclopropanation adduct analogue of PCBM as described in Lenes et al. Advanced Materials 2008, 20, 2116-2119, or bisindenofullerenes. Of course, the selection of the fullerene will need to take into account its stability to the proposed thermocleavage conditions required for the precursor to be converted to the light harvesting polymer, where a precursor is used.

Where an aqueous ink is used for coating of the active layer, it has been found by the present inventors that PCBM can be suspended in an aqueous solution by first dissolving it in THF and then adding this solution to water or an aqueous solution. It has been discovered by Deguchi et al (Langmuir 2001, 17, 6013-6017) that it is possible to form aqueous dispersions of C₆₀ and C₇₀ by preparing a saturated solution of the fullerene in THF and injection of the solution into the same volume of water followed by purging with N₂ to remove the THF. Thus, it seems plausible that other fullerenes known for use in solar cell active layers (such as those recited above) could be suspended in an aqueous solution for use in the present invention. An alternative is to use fullerene derivatives designed to have improved water solubility. The present inventors have developed a novel fullerene which may suitably be used in the present invention, which is shown below as Compound 2:

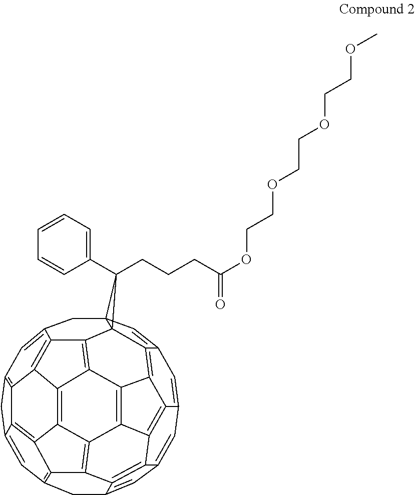 [SMILES: COCCOCCOCCOC(=O)CCCC1(c2ccccc2)C23C=c4cc5cc6cc7c8c6c6c5c5c4C21c1c2c(cc4c9c%10c(cc(c%11c%10c%10c(c1c5c6c%10c8%11)c29)C7)C4)C3]

Compound 2 requires dissolution in THF and then addition of the THF solution to water for use in the present invention, as for PCBM. The synthetic route to the fullerene is described below in the examples.

A preferred coating ink for the active layer comprises P3HT and a fullerene, preferably PCBM. Another preferred coating ink for the active layer comprises Compound 1 and a fullerene, preferably PCBM.

There are various considerations which determine the optimum thickness of the active layer.

An exciton is generated at the spot where a photon is absorbed. This occurs throughout the active layer, but mostly close to the transparent electrode. In order to generate electricity, the exciton has to reach a dissociation location (for example the electrode surface, or the light harvesting polymer/fullerene interface) and the charge carrier has to reach an electrode (holes and electrons go to opposite electrodes).

The thicker the active layer, the more likely photon absorption is to take place. A certain thickness is required in order to absorb sufficient light. A thickness giving an absorbance of around 1 (this corresponds to 90% absorbance of the light) is preferable.

However, if the thickness is too high the average distance that an exciton or a charge carrier (a hole or an electron) has to diffuse becomes too long, because of the possibility that the exciton will recombine and produce heat, or that a free hole will meet a free electron and recombine.

The optimum thickness also depends on manufacturing considerations. Some techniques give thick films and others give thin films. It is possible to form thick layers by repetition of the film deposition step (c) (including where appropriate the thermocleavage step) to build up a layer of the desired thickness. This is of particular interest where a layer is desired of greater thickness than is obtainable by, for example, a coating operation, or where a method of layer formation is used that is prone to the formation of defects. For example, in screen printing the film quality can be lower in the sense that there are sometimes point defects, which may lead to short circuit of the device. As a practical solution to this a second print (optionally associated with removal of the screen mask) generally does not generate a point defect in the same spot. Therefore it is advantageous when screen printing films to make a layer from more than one screen printing step.

As the film thickness increases, the chance of film defects (holes that allows the two electrodes to touch) leading to a short circuit decreases.

Taking all these factors into consideration, it is preferred for the active layer to have a thickness of at least 10 nm. Preferred thicknesses are in the range of 30 nm to 300 nm, for example about 100 nm. If a multilayer structure is adopted, such as in a tandem cell, a larger range of thicknesses can be accommodated. For example, in a tandem cell, each active layer thickness is in the range of about 30-300 nm. In addition to this is the thickness of the electron transporting layers and the hole transporting layers. This means that the entire thickness of the tandem device is in the range of 100-1500 nm where a single junction device is created (i.e. there are two active layers).

Suitably, the hole transport layer may be formed from conducting polymers such as PEDOT:PSS, PEDOT:PTS, vapour phase deposited PEDOT, polyprodot, polyaniline, polypyrrole, or V₂O₅ or MoO₃. Of these, V₂O₅ and MoO₃ are less preferred as they cannot be coated from aqueous solution but must be coated from alcoholic solution, and it is of course preferred in this invention to use aqueous solutions wherever possible. PEDOT:PSS is the most preferred of the hole conducting polymers listed above.

The hole transport layer may be formed by any method known in the art. However, it is preferred that the hole transport layer is formed according to the following method:

i) coating the active layer with a solution of the hole conducting compound in water and/or an alcohol or mixture of alcohols to form a film;
ii) drying the film to form a hole transport layer.

Preferably, the solution is a mixture of water and one or more alcohols.

In most cases the solution used for coating the hole transport layer will have higher surface tension than the surface energy of the active layer. Where this is the case, it is necessary to treat the surface of the active layer in order to ensure good wetting of the active layer with the solution of the hole conducting compound. Usually, when one wishes to coat an aqueous solution on, for example, PET, one would treat the surface of the PET with UV-ozone or corona treatment to alter the surface energy. However, these treatments would destroy the active layer and are thus not appropriate for this coating step. Accordingly, where it is required to treat the surface of the active layer in order that the coating ink for the hole transport layer wets the active layer, it is preferred to wet the active layer with alcohol prior to coating with the coating ink. Preferably, the alcohol used for wetting the active layer and the alcohol used in the solution of the hole conducting compound are the same, and more preferably the alcohol is selected from the group consisting of isopropanol, butanol, octanol and mixtures thereof. Most preferably, the alcohol is isopropanol.

Preferably, the second electrode is formed of a highly conductive layer that may distribute charge over the whole of its surface. Preferably, the second electrode has a work function chosen with reference to the work function of the first electrode. Preferably, the difference between the work functions of the two electrodes is at least 0.0-3.0 eV, such as 0.0-1.0 eV. It is possible for the two electrodes to have the same work function, or to be identical.

Suitably, the second electrode layer is a thick PEDOT:PSS layer. However, as the conductivity of PEDOT:PSS alone is relatively poor, it is preferred to use PEDOT:PSS as a hole transporting layer and to use a more highly conductive substance such as a metal as the electrode layer.

Suitably, where the second electrode comprises a metal layer as the highly conductive layer, it is formed by coating of a dispersion of metal particles to form a thin layer. Preferably the metal electrode layer is formed by coating an ink comprising metal flakes, water and a water-soluble binder on to the hole transport layer and drying the said ink. The ink may be applied using pad printing, doctor blading, casting, screen printing, or roll coating. In view of the aims of the present invention, it is preferred to use a method compatible with large scale manufacture, most preferably screen printing.

Such a method of forming a metal electrode layer can be used for metals such as gold, silver, molybdenum and chromium.

Preferably, the metal electrode comprises silver, or consists of silver. This provides a relatively water and oxygen stable outer layer for the device, in comparison with conventionally used more reactive metals such as aluminium.

It is found that the device constructed in this fashion is robust. In particular, the second electrode formed as described above is scratch-resistant and much less prone to short circuits than conventional vapour deposited electrodes.

It may be advantageous in certain embodiments of the device if the transparent first electrode is the cathode. This avoids the use of low work function metals as electrodes. As such low work function metals are generally highly reactive with water and oxygen in the ambient environment, avoidance of their use improves the stability of the device. Suitably, both electrodes may be formed from PEDOT-PSS, if an electron transport layer is provided between the active layer and one of the PEDOT:PSS layers.

In a fifth aspect, the present invention provides an optoelectronic device comprising an electron transporting layer which comprises zinc oxide and a wetting agent.

Preferably, the wetting agent is Zonyl® FSO-100 (2-(perfluoroalkyl)ethanol, CAS No 65545-80-4) or Triton® X-100 (polyethylene glycol p-(1,1,3,3-tetramethylbutyl)-phenyl ether, CAS No 9002-93-1). Preferably, the amount of Zonyl® FSO-100 present is between 1.4 wt % and 20 wt %, more preferably between 3 wt % and 8 wt %, compared with ZnO, or the amount of Triton® X-100 present is between 1.4 wt % and 68 wt %, more preferably 24 wt %, compared with ZnO. Most preferably, the wetting agent is Zonyl® FSO-100 (2-(perfluoroalkyl)ethanol, CAS No 65545-80-4).

### BRIEF DESCRIPTION OF THE FIGURES

FIG. 1 shows a typical I-V curve and an I-V curve with an inflection point.

FIG. 2 shows a diagram illustrating I_{SC}, V_{OC} and the maximum power of the device Pₘₐₓ.

FIG. 3 shows a schematic diagram of a cross section through a device made according to the method of the present invention.

FIG. 4 shows apparatus appropriate for use in the present invention.

FIG. 5 shows the synthesis of compound 1 and fullerene 2.

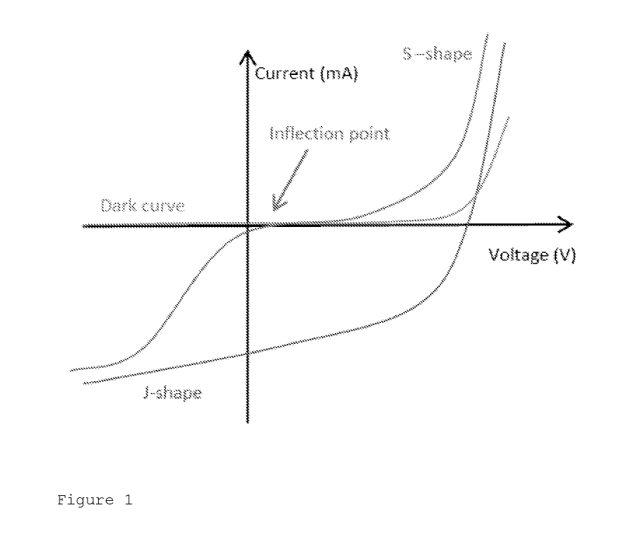

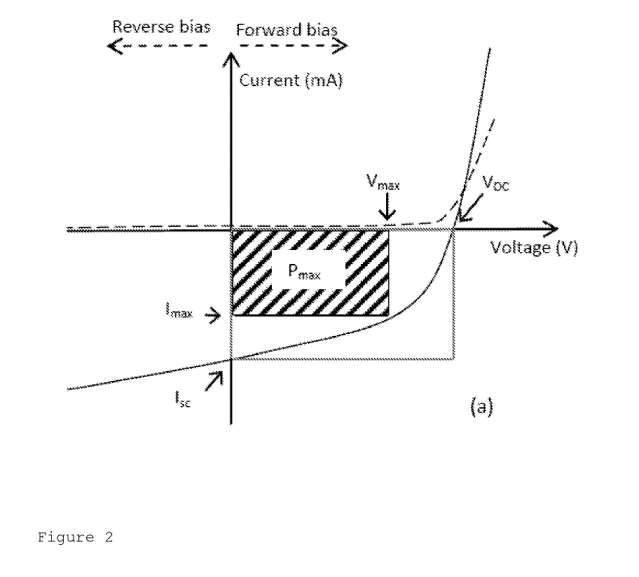

### DETAILED DESCRIPTION

### General Description of the Function of the Photovoltaic Device and its Individual Layers

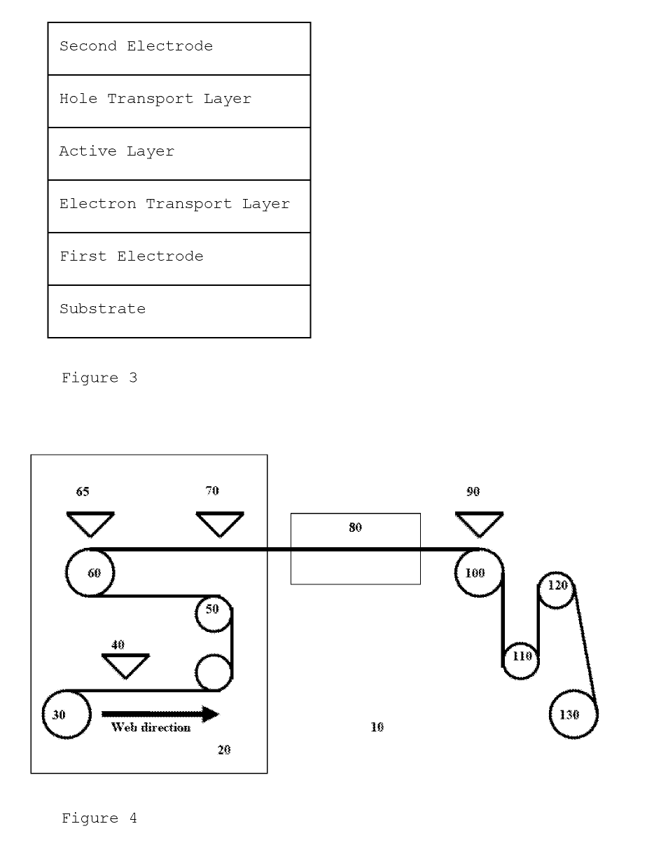

The device and its layers are described with reference to FIG. 3.

Electrode layers: One of the electrodes is necessarily transparent and both electrodes may be transparent. Typically, the first electrode is the front electrode and therefore it is transparent. The back electrode does not need to be transparent. The purpose of the front electrode is to admit light to the device film. The first electrode may be a pure transparent conductor (a transparent conducting oxide such as ITO or PEDOT) or it may be a composite of a conducting metal grid allowing from some light to come through with a conducting polymer on top (such as PEDOT:PSS, PEDOT:PTS, polyprodot, polyaniline, polypyrrole or other similar conducting polymers known in the art).

The zinc oxide layer functions as an electron transporting layer. The zinc oxide layer is placed on top of the first electrode. The ZnO is optically transparent (no colour) and only transports electrons.

Active layer: this comprises a mixture of the light harvesting polymer and an electron acceptor (e.g. a fullerene or a transition metal oxide). In this layer light is absorbed to form an exciton, and the exciton dissociated to a hole and an electron that can percolate through the interpenetrating network of polymer and electron acceptor. The majority of holes are transported in the polymer and the majority of electrons are transported in the electron acceptor.

On top of the active layer PEDOT:PSS or a similar conducting polymer is employed as a hole transporting layer.

Second/back electrode: Any highly conducting material such as a metal. The purpose is to remove the charges as efficiently as possible.

Explanation of the working of the device: The charges generated in the active layer can diffuse round in the two interpenetrating networks (holes in the polymer network and electrons in the electron acceptor network). However electrons can only leave through the electron transporting layer and holes can only leave through the hole transporting layer. Thus, an electrical potential difference is created between the two electrodes.

The cells may be realised in reverse order.

Tandem cells: When stacking cells the holes coming through the hole transporting layer from the first cell meet the electrons in the metal oxide layer coming from the next cell and recombine. The result is that the voltage of the first and the second cell are added. However if the first and the second cell do not produce roughly the same amount of charge some charges are lost in the recombination layer between the first and second cell, i.e. some of the holes or electrons will not find a partner to recombine with.

Description of the Manufacture of the Device

As substrates with ITO provided thereon are commercially available, in particular substrates of PET or other flexible polymers suitable for use in a roll-to-roll printing process, this is a practical choice for the starting point for this method. Patterning of the ITO layer on a purchased substrate may be carried out as is known in the art. In particular, where a roll-to-roll process is to be used to produce the devices, the method described in Krebs et al. Solar Energy Materials and Solar Cells 2009, 93, 465-475 is used. In that method, the pattern is created by roll-to-roll printing an etch resist in the desired pattern, etching the ITO layer using a roll-to-roll etching bath, and washing and drying the substrate.

The coating ink for the electron transport layer is then roll to roll coated in the desired pattern relative to the ITO pattern. Suitably, slot-die or knife over edge coating is used. The web is then passed through the oven to be heat treated at 140° C. for at least 5 min to convert the zinc acetate in the ink to zinc oxide, and create a functional electron transport layer.

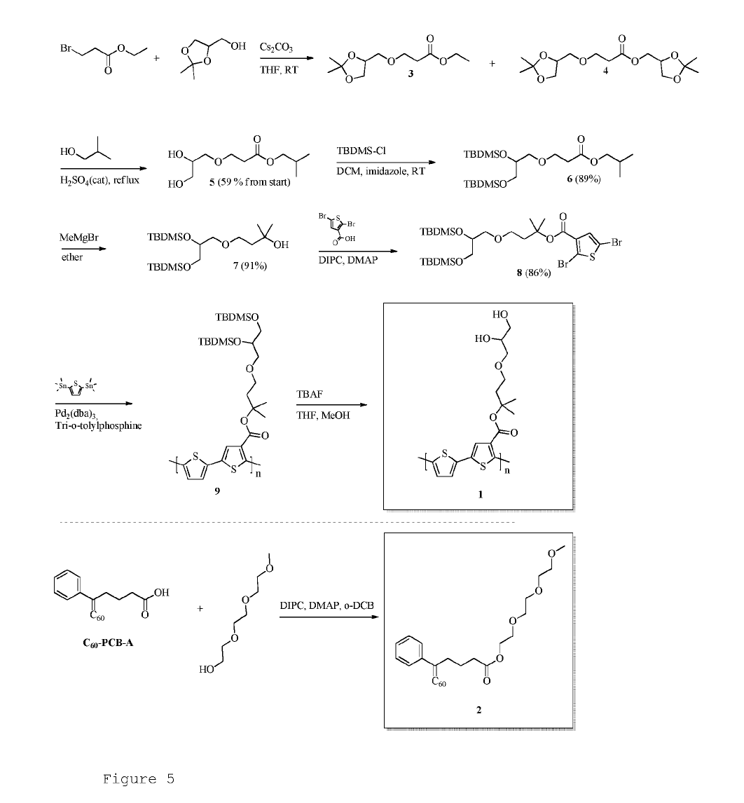

The coating of the active layer will be described with reference to FIG. 4, in which is shown an apparatus 10 suitable for carrying out coating and drying of a layer on a flexible substrate that can be wound from roll to roll (a web) and subsequent heat treating of the layer. It will be understood that very similar apparatus can be used for coating, drying and, where necessary, heat treating the other layers formed in the device.

The web 35 has a width of 280-305 mm, and is mounted on an unwinder 30, supported on tension rollers 50, 110, and collected after heating on a winder 130. The system may be run at web speeds of 0.2-2 m min⁻¹, and is operated in tension control with a tension on the web of 140 N. A printing station 20 is provided immediately downstream of unwinder 30, comprising a corona treatment apparatus 40, coating machine 65 and coating roller 60 for coating the required layers on to web 35, and IR lamp 70 in that order in the downstream direction. The coating machine used may suitably be a roll-to-roll coater, such as a modified basecoater from SolarCoatingMachinery GmbH, Germany. This coating machine has a roll width of 30 cm and a working width of 25 cm. Coating roller 60 may suitably be of 100 mm diameter, which permits the use of knife-over-edge coating, slot-die coating and gravure coating techniques. Downstream of the printing station 20 is provided oven 80, through which the web 35 passes. Oven 80 may suitably be heated by means of hot air, in particular by providing hot air inflow to heat the oven and air extraction to remove cooled air and any volatile substances which have vapourised during heating in the oven. The oven heats both surfaces of the web. A suitable operating temperature for the oven is 140° C. when the web is made from PET.

Downstream of oven 80 may be provided an LED lamp 90 and a cooling roller 100 which is in contact with the web 35 in the field of illumination of the LED lamp 90. This is provided for the thermocleavage of the precursor to the light harvesting polymer, where that is used to form the active layer. Alternatively, the thermocleavage may be carried out by heating of the active layer in an oven as has been described above.

The high power LED array 90 measures 11×273.5 mm and comprise an array of 182 lines (connected in parallel) of 7 diodes (connected in series). The array has a total of 1274 LED diodes that are attached to a silvered copper bar and the individual chips are wire bonded for connectivity. The copper bar is attached to a water cooled aluminium block. The LED array has a nominal current of 63.7 Amperes at 24 V and can be pulsed with higher currents at lower duty cycle. The system is typically operated at 33% duty cycle and 200 amperes of current, with a pulse length of 330 ms and thus a frequency of 1 Hz. The diode array 90 is positioned to be in close proximity to the web 35. The distance between the surface of the array 90 and web 35 is typically 1-10 mm, and may be adjusted depending on the film absorbance and web speed. Cooling roller 100 is suitably maintained at a temperature of 16° C., and may be water-cooled. A speed measuring roller 120 is provided to monitor the web speed in a suitable position, such as downstream of LED array 90. In addition, instrumentation such as temperature sensors, micropumps for controlling the coating process, and videocameras for viewing the web during the coating and drying process, in order to determine the thickness, evenness, dryness etc. of the coated layer, are provided (not shown). Optionally, a shadow mask (not shown) can be placed between the LED source 90 and the web 35 to pattern the illuminated area and thus the areas of the film that are cleaved. A washing step can then be used to remove uncleaved material after the illumination and thermocleavage.

In use for coating the active layer, where the active layer comprises a precursor of a light harvesting polymer, web 35 is mounted on unwinder 30 and passed over the tension roller 50, and coating roller 60, through oven 80, over cooling roller 100, tension roller 110, speed measuring roller 120 and attached to winder 130. The winder 130 and unwinder 30 then are operated such that the web passes over the speed measuring roller 120 at a speed of 0.2-2 m min⁻¹, with the tension rollers 50, 110 maintining a tension of 140 N on the web. The web passes under the corona treatment apparatus, and undergoes corona treatment, then, after passing over tension roller 50, passes over coating roller 60 and under coating head 65, during which the thermocleavable polymer/electron acceptor layer is applied to the web 35 by slot-die or knife-over-edge coating of a solution of the thermocleavable polymer and the electron acceptor. The coated web then passes under IR lamps 70, which dry the solvent from the coated layer. The web then enters the oven 80, and is heated to close to the maximum temperature tolerated by the web. For example, where the web is PET, the oven is maintained at 140° C. Any volatile compounds produced by the web or thermocleavable layer, for example any remaining solvent in the thermocleavable layer, are removed from the oven by the air extraction system. Once heated, the web then passes under LED array 90 and simultaneously over cooling roller 100. The web speed and the LED array operation parameters (i.e. LED power, pulse duration and frequency, and distance from the web) are chosen such that the thermocleavable polymer in the active layer is thermocleaved without detrimental heating of the web 35. The cooling action of the cooling roller 100 in contact with web 35 allows a more powerful illumination of the web than would be possible in its absence. Once the polymer has been thermocleaved, the web passes over tension roller 110 and speed measuring roller 120, and is collected on winder 130.

Alternatively, thermocleavage of the active layer may be achieved by heating the web by passage through the oven at a suitable temperature at a speed such that the thermocleavage is complete once the web has passed through the oven. As a further alternative, the separate devices or modules printed on the web can be separated from one another by cutting the web in appropriate places and the separate devices or modules can be heat treated in a static oven under the required conditions. Clearly, if this last method is used, subsequent processing steps must be carried out on the individual devices or modules and not in a roll-to-roll process.

In order to coat the hole transport layer, the surface of the active layer is wetted with an alcohol, such as isopropanol, and the coating ink for the hole transport layer coated on the active layer by slot-die coating and dried. The hole transport layer is based on PEDOT:PSS and most of the commercially available formulations can be used whether they are entirely aqueous formulations, screen printing formulations or low water content formulations. It is however important to have a significant alcohol, such as isopropanol, content in the ink.

The second electrode layer is then applied by screen printing of an aqueous silver paste and drying using air. The silver paste comprises silver flake mixed with an aqueous binder and water, and optionally comprises a UV curing agent. Where a UV curing agent is provided in the paste, the layer can be UV cured once coated.

The devices can then be separated from one another by cutting the substrate at appropriate places, and, if considered necessary, the devices can be matured to improve their performance, and the devices can be encapsulated according to known methods to exclude the ambient atmosphere and moisture.

Development of the Synthesis of Compound 1

The final synthetic procedure is outlined in FIG. 5.

Initial treatment of a mixture of ethyl 3-bromopropanoate and solketal with Cs₂CO₃ as base in order to minimize side reactions, such as transesterification and Claisen condensation, yielded a mixture of 5 and 6. This mixture was treated with isobutanol in the presence of catalytic amount of acid in order to deprotect the diol and simultaneously transform both compounds into the corresponding iso-butylester 7. This facilitates workup and separation from the simultaneously formed glycerol.

Double TBDMS-protection of 7 afforded 8 almost quantitatively. Subsequent treatment of 8 with methylmagnesium bromide afforded the tertiary alcohol 9. The tertiary alcohol was coupled with 2,5-dibromothiophene-3-carboxylic acid to give 10 in good yield by direct treatment with diisopropylcarbodiimide (DIPC) and DMAP. This was done without the use of scandium triflate or hafnium chloride catalysts which have previously been reported as good catalysts in combination with DIPC and DMAP for preparation of tertiary alcohols. In fact the use of the catalysts resulted in a number of unwanted side products, an effect which can probably be ascribed to coordination of the catalyst not only to the tertiary alcohol but also to the multiple other oxygen atoms in the side chain.

Polymerisation of 9 with 2,5-bis(trimethylstannyl)-thiophene in a Stille coupling afforded the polymer 11 which, because of the TBDMS-protected alcohols, could undergo the normal procedures of workup such as removal of salts by precipitation in MeOH and soxhlet extraction with MeOH-procedures that would not be applicable to a polymer soluble in aqueous solution. Removal of the TBDMS-groups was performed with TBAF in initially pure THF solution which later had to be diluted with MeOH as the final polymer is not soluble in pure THF. The polymer appeared to be soluble only in DMF and DMSO when using pure solvents, but surprisingly also showed to be soluble in a mixture of equal amounts water and isopropanol when a little THF was present (down to 4% Vol.).

Development of the Synthesis of Fullerene 2

As it was initially thought impossible to process PCBM in aqueous solution, the preparation of corresponding acceptor materials having greater water solubility was explored. A PCBM-analogue, 2, containing ethereal ester side chains (instead of methyl esters) were prepared from commercial C₆₀-PCB-A as shown in FIG. 5.

In the preparation of 2, C₆₀-PCB-A was coupled with commercially available triethyleneglycol mono methyl ether using DIPC and DMAP in o-dichlorobenzene. The purified fullerene was soluble in polar aprotic solvents (DMF, DMSO, THF), but precipitated from these when water or alcohols were added. It was later found to be possible to suspend this fullerene in water by adding a solution of the fullerene in THF to water, as described above.

### EXAMPLES

Set out below are a number of different ink compositions for the formation of a zinc oxide layer, evaluated for their coating, adhesion and inflection point properties within a photovoltaic device. Further, the processes used to create the devices having the zinc oxide layers produced from the different inks and the methods of assessing the device performance are set out.

### Comparative Example 1

### Preparation of ZnO Nanoparticle Inks

Zn(OAc)₂.2H₂O (59.4 g) was dissolved in MeOH (2500 mL) and heated to 60° C. KOH (30.2 g) was dissolved in MeOH (1500 mL), heated to 60° C. and added to the stirred zinc acetate solution (Both solutions were boiling when mixing). No precipitation took place to begin with (maybe due to the boiling). The precipitate dissolved after a few minutes at reflux. The temperature was maintained at 60° C. and the mixture was kept at gentle reflux for 3 h. The mixture was then cooled without stirring and allowed to settle for 6 h and then resuspended in MeOH (2.5 L) and allowed to settle overnight (>16 hours). The supernatant was decanted and the solid resuspended in the desired solvent (80 mL). o-Xylene, chlorobenzene, acetone have been employed. 1 mL of the final solution was evaporated at 100° C. for 1 hour and the concentration of ZnO determined. The stabilizer (methoxyethoxyacetic acid) was added to 10% w/w with respect to ZnO. The solution was then microfiltered (0.45 micron) and was stable for many months under ambient conditions in a tightly closed container. Protection from humidity is necessary.

In some cases, AlOH(OAc)₂ was added to the ZnO nanoparticle inks in an amount of 0.1-10% w/w with respect to ZnO after preparation of the nanoparticles. Attempts to include aluminium salts during nanoparticle precipitation failed to yield dispersible nanoparticles of ZnO but led to precipitation of insoluble material.

### Comparative Example 2

### Preparation of Inks Containing Zn(OAc)₂.2H₂O with No Wetting Agent

The solutions were prepared by dissolving 20 g of Zn(OAc)₂.2H₂O and optionally 0.1-1.2 g of Al(OH)(OAc)₂ in the desired solvent by stirring for 2 h according to the following compositions:

Methanol: 20 g of Zn(OAc)₂.2H₂O, 0.2 g of Al(OH)(OAc)₂

Water: 20 g of Zn(OAc)₂.2H₂O

Water: 20 g of Zn(OAc)₂.2H₂O, 0.3 g of Al(OH)(OAc)₂

The inks were filtered through a 0.45 micron filter to remove insoluble material prior to use.

### Example 1

### Preparation of Inks Containing Zn(OAc)₂.2H₂O with a Wetting Agent

The solutions were prepared by dissolving 20 g of Zn(OAc)₂.2H₂O, a wetting agent (0.1-1.5 g of FSO-100 or 0.1-5 g of Triton X-100), and optionally 0.1-1.2 g of Al(OH)(OAc)₂, by stirring for 2 h in the desired solvent according to the following compositions:

Methanol: 20 g of Zn(OAc)₂.2H₂O, 0.2 g of Al(OH)(OAc)₂ and 0.2 g of FSO-100

Water: 20 g of Zn(OAc)₂.2H₂O, 0.3 g of Al(OH)(OAc)₂ and 0.6 g of FSO-100

Water: 20 g of Zn(OAc)₂.2H₂O, 0.6 g of FSO-100

Water: 20 g of Zn(OAc)₂.2H₂O, 0.3 g of Al(OH)(OAc)₂ and 1.8 g of Triton X-100

Water: 20 g of Zn(OAc)₂.2H₂O, 1.8 g of Triton X-100

The inks were filtered through a 0.45 micron filter to remove insoluble material prior to use.

### Example 2

### Device Preparation

ITO coated glass substrates (25 mm×50 mm) with a sheet resistivity of 8-12 ohm square⁻¹ were employed. The ITO was etched away in one end of the substrate to allow for contacting to the top electrode without short-circuiting the devices. The substrate was cleaned by submersion successively in chloroform, acetone, water and isopropanol for 5 min using ultrasound. The slides were drawn from the isopropanol immediately prior to use, placed on the spin coater and spun dry immediately before application of the layers. The zinc oxide layers detailed in the examples below were applied and treated as described below. Following on from the zinc oxide layer the devices were completed as follows. The active layer comprised P3HT (15 mg mL⁻¹) and PCBM (12 mg mL⁻¹) dissolved in chlorobenzene. This solution was heated and microfiltered (0.45 micron) immediately prior to use and was spincoated at 1000 rpm followed by annealing at 140° C. for 2 min. PEDOT:PSS (Agfa EL-P 5010 diluted with 50% w/w isopropanol to a viscosity of around 270 mPa s) was applied on top of the active layer by firstly wetting the active layer with isopropanol followed by spinning at 100 rpm until the isopropanol was dried off, followed immediately by application of the PEDOT:PSS solution. The PEDOT:PSS film was dried on a hot plate at 140° C. for 5 min. A silver grid electrode was screen printed using silver ink (Dupont PV410) and the print dried for 3 min at 140° C. The active area of the device was 3 cm². Finally the device was protected by lamination of a barrier foil towards the backside of the device. A UV-filter with a cut-off at 390 nm was applied to the front side. All manipulation and preparation was carried out in air. The devices were tested under a solar simulator (Steuernagel KHS575) with an incident light intensity of 1000 W m⁻² AM1.5G. The typical device temperature was 72±2° C. In the figure below a curve with and without inflection point is shown. The typical performance reached was 1.7-2.5% for good inflection free devices and 0.001-0.1% for devices presenting various levels of inflection. For inflection free devices I_{sc}=8.5-10.5 mA cm⁻², V_{oc}=0.4-0.55V, FF=35-45%.

For the coating of the zinc oxide layer, the solutions containing zinc acetate prepared as described above were spincoated at 1000 rpm and annealed on the hot plate at 140° C. for 10 min after preparation. At least 5 minutes of annealing was required to convert the zinc acetate substantially to zinc oxide and thus to produce a functioning electron transport layer. After 10 min only a slight improvement was observed up to around 40 min of heating. More than 40 min of heating did not yield any change/improvement.

For the inks containing ZnO nanoparticles, the ink is spincoated at 1000 rpm and annealed on the hotplate at 140° C. for 2 to 5 min in order to make the layer insoluble.

### Example 3

### Comparison of the Device Properties

Adhesion is difficult to compare in a quantitative manner, although in most cases one can make the observation that a particular coating, overlayer, multilayer etc. “sticks” more or less well in a comparative sense. In cases where the tape test (ASTM D 3359-09) or knife test (ASTM D 6677-07) are not applicable it is even more challenging to quantify. In the table below the adhesion is termed “good” if the cured ZnO film is not easily removed just after coating and is impossible to remove after heating for 10 min at 140° C. when forcing a cotton bud wetted with water or solvent (i.e. acetone, chlorobenzene) across the film. The adhesion is termed “intermediate” if it is possible to run the cotton bud wetted in solvent gently over the film without removal of the film. The adhesion is termed “poor” if the gentle touch of the cotton bud removes the film or leaves scratches in it.

Inflection. The IV curves for the devices were recorded with a UV-filter having a cut-off for all wavelengths below 390 nm. The inflection point in the IV-curve could be “strong” meaning that prolonged illumination with UV-light would lead to gradual removal of the inflection. Keeping the device in the dark would make the inflection point reappear. “Mild” inflection means that an inflection point was typically slightly visible but that it was static i.e. independent of illumination with UV-light. It did not change over time or with keeping of the device in the dark. “None” means that the IV-curve did not present an inflection point under any conditions, illumination, dark etc.

Coating refers to spin coating or slot-die coating of the liquid (ink) on ITO-films on either glass or PET (for R2R coating). “Poor” means that no covering films were obtained. “Intermediate” means that it was possible to obtain partial films but also that they were not of practical use. “Good” means that it coats well in a practical sense, i.e. for R2R slot-die coating only “good” coating inks could be used for patterning into stripes.

Detergents. Triton X-100 essentially worked as well as FSO-100. The coating was as good but it should be said that 3 times higher quantities were required to achieve the same quality of coating behavior as with FSO-100. As explained previously, it is desirable to keep the amount of additives as low as possible in functional layers.

The results of the assessment are shown below in Table 1:

TABLE 1

| Ink | Solvent | Adhesion | Inflection | Coating |
|---|---|---|---|---|
| ZnO | Chloro- | intermediate | Strong | intermediate |
| nanoparticles | benzene | | | |
| ZnO | Acetone | intermediate | Strong | good |
| nanoparticles | | | | |
| ZnO | Acetone | intermediate | Strong | good |
| nanoparticles + | | | | |
| Al(OH)(OAc)₂ | | | | |
| Zn(OAc)₂ | Methanol | poor | Strong | poor |
| Zn(OAc)₂ + | Methanol | good | mild | good |
| Al(OH)(OAc)₂ | | | | |
| Zn(OAc)₂ + | Methanol | good | None | good |
| Al(OH)(OAc)₂ + | | | | |
| FSO-100 | | | | |
| Zn(OAc)₂ | Water | Poor | Strong | poor |
| Zn(OAc)₂ + | Water | good | Mild | poor |
| Al(OH)(OAc)₂ | | | | |
| Zn(OAc)₂ + | Water | good | None | good |
| Al(OH)(OAc)₂ + | | | | |
| FSO-100 | | | | |
| Zn(OAc)₂ + | Water | poor | None | good |
| FSO-100 | | | | |
| Zn(OAc)₂ + | Water | poor | None | good |
| Triton X-100 | | | | |
| Zn(OAc)₂ + | Water | good | None | good |
| Al(OH)(OAc)₂ + | | | | |
| Triton X-100 | | | | |

Thus, it can be seen that in order to avoid the formation of a device with an inflection point, the use of a wetting agent in a Zn(OAc)₂ containing ink is essential. In order to obtain good adhesion of the resulting ZnO layer to the underlying layers, the addition of AlOH(OAc)₂ is required.

### Example 4

### Preferred Ink Composition for the Electron Transport Layer

Zn(OAc)₂.2H₂O (20 g), AlOH(OAc)₂ (0.3 g) and Zonyl FSO-100 (2-(perfluoroalkyl)ethanol, CAS No 65545-80-4) (0.6 g) were mixed in 200 ml of demineralised water. The mixture was stirred for 2 h and filtered through a 0.45 micron filter to remove insoluble material. The ink was used directly thereafter and could be stored for many months without noticeable change in performance when subsequently used. The ink could be spin-coated or roll-to-roll coated.

### Example 5

### Formation of the ZnO Layer

Roll-to-roll process: A PET/ITO substrate was used. Slot-die coating of the ink of Example 1 was carried out with corona treatment prior to coating (500 W) (UV-ozone treatment for 5 min could also be used instead of corona treatment). A web speed of 2 m min⁻¹ was employed and the pumping rate adjusted such that a wet layer thickness of 3-4 micron was obtained. The drying temperature was 140° C. and the oven length was 1 m. This gave a dry film that needed to be heat treated to convert the zinc acetate substantially to zinc oxide. The heat treatment was carried out by passage of the dried layer through an oven 4 m long at 0.2 m min⁻¹. This gave a total drying time of 0.5 min and a total curing time of 20 min. Completion of the conversion was observed by change in colour of the film from yellow-green to bluish-brown.

Spin-coating process: A glass/ITO substrate was used. The ITO substrates were first cleaned in isopropanol and water for 10 minutes each in an ultrasound bath. The ink of Example 1 was then spincoated on to the ITO layer at 1000 rpm. The ink layer was dried and then heat treated at 140° C. for at least 5 min to yield a zinc oxide film. Completion of the conversion was observed by change in colour of the film from yellow-green to bluish-brown.

### Example 6

### Synthesis of Compound 1

### Synthesis of 2,5-dibromothiophene-3-carboxylic acid

This compound was synthesised according to the method described in J. S. Liu, E. N. Kadnikova, Y. X. Liu, M. D. McGehee and J. M. J. Frechet, J. Am. Chem. Soc. 2004, 126, 9486-9487.

Synthesis of Compounds 3 and 4

A mixture of ethyl 3-bromopropanoate (18.00 g, 97 mmol), solketal (17.25 g, 128 mmol) and CeCO₃ (63.55 g, 195 mmol) was mixed in THF (40 ml) under argon and left while stirring at RT for 6 days. In order to remove the colloid dispersion of inorganics, the mixture was diluted with DCM, centrifuged and the organic layer was separated by decantation. The inorganic part was extracted with DCM (3×150 ml) which was separated by centrifugation/decantation. The collected organic fractions were then passed through a very short silica column in order to remove the last traces of both colloid and dissolved inorganics. Removal of the solvents yielded a crude mixture of 25.3 g. This mixture was used without further purification in the next step.

Synthesis of Compound 5

The crude mixture of 3 and 4 (97 mmol) was dissolved in isobutanol (1 L) and 98% sulfuric acid (1.00 ml, 18.8 mmol) was added. The mixture was left at 37° C. for 14 h at reduced pressure (15 mbar) in order to remove evolving acetone and ethanol. Potassium tert-butoxide (4.21 g, 37.5 mmol) and then NaHCO₃ (0.25 g, 3 mmol) were then added in order to ensure neutralization of the acid, followed by removal of the solvent at reduced pressure. The resulting clear oil was purified by column chromatography on silica (AcOEt as solvent) yielding 7 as a clear oil (12.7 g, 59%).

¹H NMR (500 MHz, CDCl₃) δ 3.89 (d, J=6.7 Hz, 2H), 3.87-3.83 (m, 1H), 3.81-3.71 (m, 2H), 3.71-3.49 (m, 4H), 2.84-2.37 (m, 4H), 1.93 (h, J=6.7 Hz, 1H), 0.92 (d, J=6.6 Hz, 6H). ¹³C NMR (126 MHz, CDCl₃) δ 172.09, 72.63, 71.00, 70.52, 66.86, 64.00, 35.03, 27.82, 19.16. HR-MS (ESI) m/z for M+H (C10H21O5): calc. 221.1389. Found: 221.1391.

Synthesis of Compound 6

Compound 5 (3.78 g, 17.2 mmol) in DCM (25 ml) was cooled on an ice bath and imidazole (2.35 g, 34.5 mmol) was added. The mixture was allowed to stir for approx 10 min and TBDMS-Cl (5.18 g, 34.4 mmol) in DCM (6 ml) was added leading to a heavy white precipitate. After stirring for hour the ice bath was removed and the mixture was stirred at RT overnight. Heptane (20 ml) was added to the mixture followed by removal of the precipitate by filtration. Column chromatography on silica using heptane/ethyl acetate with gradient steps of 2% yielded the pure product as a clear oil. (6.87 g, 89%).

¹H NMR (500 MHz, CDCl₃) δ 3.87 (d, J=6.7 Hz, 2H), 3.83-3.66 (m, 3H), 3.57-3.45 (m, 3H), 3.37 (dd, J=9.9, 5.9 Hz, 1H), 2.58 (t, J=6.6 Hz, 2H), 1.93 (h, J=6.7 Hz, 1H), 0.93 (d, J=6.7 Hz, 6H), 0.88 (2×s, 18H), 0.05 (2×s, 12H). ¹³C NMR (126 MHz, CDCl₃) δ 171.78, 73.31, 72.84, 70.74, 67.08, 65.26, 35.41, 27.86, 26.10, 26.01, 19.23, 18.49, 18.34, −4.48, −4.53, −5.22, −5.28. HR-MS (ESI) m/z for M+H(C₂₂H₄₉O₅Si₂): calc. 449.3119. Found: 449.3051.

Synthesis of Compound 7

Methylmagnesium bromide (3 M, 11.85 ml, 35.6 mmol) was added by syringe to a solution of 6 (5.32 g, 11.85 mmol) in ether (30 ml) under argon resulting in a white precipitate. After stirring for hours at RT the reaction was quenched with saturated NaHCO₃ (50 ml) followed by addition of 1M HCl until CO₂ evolution was observed. The ethereal phase was separated followed by extraction of the aqueous phase with additional ether (4×50 ml). The combined organic fractions were washed with water and brine. After drying over MgSO₄ the solvent was removed in vacuo to yield a crude oil (4.68 g). Purification by on a silica column using Heptane/AcOEt (4:1) as eluent yielded the pure product as a clear oil (4.38 g, 91%)

¹H NMR (500 MHz, CDCl₃) δ 3.68 (dt, J=10.5, 5.2, 1H), 3.64-3.51 (m, 2H), 3.50-3.29 (m, 4H), 3.09 (s, 1H), 1.76-1.55 (m, 2H), 1.14 (d, J=1.5, 6H), 0.79 (2×s, 18H), 0.11-0.23 (m, 12H). ¹³C NMR (126 MHz, CDCl₃) δ 73.25, 72.57, 70.58, 69.26, 64.82, 41.64, 29.74, 29.20, 26.08, 25.99, 18.47, 18.27, −4.45, −4.55, −5.22, −5.27. HR-MS (ESI) m/z for M+H (C₂₀H₄₇O₄Si₂): Calc.: 407.3013. Found: 407.3007. Microanalysis for C₂₀H₄₆O₄Si₂: Calc.: C, 59.1; H, 11.4. Found: C, 58.8; H: 11.3.

Synthesis of Compound 8

A mixture of 7 (0.6 g, 1.475 mmol), 2,5-dibromothiophene-3-carboxylic acid (0.55 g, 1.923 mmol) and DMAP (0.270 g, 2.213 mmol) in DCM (4 ml) was stirred at RT for hour. Diisopropylcarbodiimide (0.297 ml, 1.918 mmol) was then added, the temperature raised to 39° C. and the mixture was left stirring for 2 days. Purification on a silica column with gradient eluent (heptanes, increasing with 1% AcOEt steps) yielded the desired product (0.85 g, 86%).

¹H NMR (500 MHz, CDCl₃) δ 7.27 (s, 1H), 2.21-2.11 (m, 2H), 1.59 (s, 6H), 0.89-0.86 (m, 18H), 0.07-0.03 (m, 12H). ¹³C NMR (126 MHz, CDCl₃) δ 159.98, 133.41, 132.08, 118.31, 111.15, 83.93, 73.10, 72.85, 67.60, 65.20, 40.46, 26.77, 26.65, 26.10, 26.01, 25.95, 18.50, 18.34, −4.43, −4.51, −5.20, −5.25. HR-MS (ESI) m/z for M+Na (C₂₅H₄₆Br₂NaO₅SSi₂): Calc.: 695.0869. found 695.0836. Microanalysis for C₂₅H₄₆Br₂O₅SSi₂: Calc.: C, 44.5; H, 6.9. Found: C, 44.5; H: 6.8.

Synthesis of Compound 9

Compound 8 (297 mg, 0.440 mmol), 2,5-bis(trimethylstannyl)thiophene (180 mg, 0.440 mmol), tri-o-tolyl phosphine (53.6 mg, 0.176 mmol) and Pd₂(dba)₃ (20.16 mg, 0.022 mmol) were mixed in ‘degassed’ dry toluene (10 ml). The temperature was raised to 110° C. and the mixture stirred for 2 days. The polymer was precipitated by adding the reaction mixture to methanol, and the solid was purified by soxhlet extraction with methanol (14 h) followed by extraction of the polymer with hexane. After evaporating the solvent, the polymer was redissolved in toluene and precipitated from methanol. (242 mg, 88%). M_{w}: 40856, Mₙ: 15314, PDI: 2.67.

Synthesis of Compound 1

Compound 9 (202 mg, 0.337 mmol) was dissolved in THF (5 ml) followed by addition of TBAF (1 M in THF) (1.35 ml, 1.35 mmol). The mixture was heated to 35° C. and left standing overnight. Methanol (2 ml) was then added and the solution stirred for an additional 24 hours. The deprotected compound was precipitated by dropwise addition to AcOEt, and filtration. The precipitate was washed extensively with isopropanol and then dried in vacuum. It was not possible to purify the polymer by chromatography.

### Example 7

### Synthesis of Fullerene 2

Synthesis of Compound 2

C₆₀—PCB-A (165 mg, 0.184 mmol) and DMAP (25 mg, 0.205 mmol) were mixed in ortho-dichlorobenzene (Volume: 20 ml). After stirring for 30 min DIPC (37 μL, 0.239 mmol) and triethyleneglycol monomethyl ether (42 μL, 0.261 mmol) were added and the temperature raised to 45° C. After 1 h the temperature was raised further to 70° C. for 24 hours. The crude solution was evaporated directly onto celite and purified by flash chromatography with toluene/AcOEt (2:1) as eluent yielding the pure product (140 mg, 72%) after evaporation of the solvent.

### Example 8

### Ink Formulations for the Remaining Device Layers

Ink for the Active Layer

Where the active layer is to comprise polymer 1 and a fullerene, the polymer (1) was dissolved in THF (10 mg/ml) and diluted with a mixture of water/isopropanol/THF (47.5:47.5:5) and the fullerene 2 or PCBM (10 mg/ml) in THF was added just prior to use. The resulting solvent system for the ink was around 52.5% THF, 25% water and 22.5% isopropanol.

Where the active layer was to be P3HT and PCBM coated from chlorobenzene, the ink was made by making up a 44 mg ml⁻¹ concentration of a 1.2:1 mixture of P3HT and PCBM in chlorobenzene.

Ink for the Hole Transport Layer

PEDOT:PSS (Agfa EL-P 5010) was diluted with isopropanol 1:1 (w/w).

Ink for the Electrode Layer

Silver flake (FS 16 from Johnson Matthey) (110 g) was mixed well with an aqueous solution of binder. The aqueous solution was prepared by mixing the binder (Viacryl 175W40WAIP from Cytec, an acrylic binder) (25 g) with water (25 g).

### Example 9

### Device Preparation

All preparative steps were carried out in air.

Laboratory Scale Device Production—Polymer 1/Fullerene Active Layer

For lab scale devices, glass substrates with an electrode pattern of indium-tin-oxide (ITO) were used (8-12 Ohm Square⁻¹). The ITO substrates were first cleaned in isopropanol and water for 10 minutes each in an ultrasound bath. The ink for the electron transport layer (zinc oxide layer) was then spincoated on to the ITO layer at 1000 rpm. The ink layer was dried and then heat treated at 140° C. for at least 5 min to yield an electron transporting film. Then, the ink for the active layer (containing polymer 1 and either fullerene 2 or PCBM) as coated on to the electron transport layer by spincoating at 400 rpm and was heated on a hotplate at 140° C. for around 20 min to obtain sufficient conversion of the polymer 1 to the carboxylic acid that the layer was insoluble when processing subsequent layers. The ink for the hole transport layer was then spincoated at 1000 rpm for 15 s on to the insoluble active layer wetted with isopropanol, and was dried by heating on a hotplate at 140° C. for 5 min. Finally, the ink for the silver electrode was screen printed on to the hole transport layer through a steel mesh (72/36) and dried by heating at 140° C. for 2 min.

Laboratory Scale Device Production—P3HT/PCBM Active Layer

For lab scale devices, glass substrates with an electrode pattern of indium-tin-oxide (ITO) were used (8-12 Ohm Square⁻¹). The ITO substrates were first cleaned in isopropanol and water for 10 minutes each in an ultrasound bath. The ink for the electron transport layer (zinc oxide layer) was then spincoated on to the ITO layer at 1000 rpm. The ink layer was dried and then heat treated at 140° C. for at least 5 min to yield an electron transporting film. Then, the ink for the active layer (comprising P3HT and PCBM in chlorobenzene as described above) was coated on to the electron transport layer by spincoating at 400 rpm and was dried at 140° C. for 2 min. The ink for the hole transport layer was then spincoated at 1000 rpm for 15 s on to the insoluble active layer wetted with isopropanol, and was dried by heating on a hotplate at 140° C. for 5 min. Finally, the ink for the silver electrode was screen printed on to the hole transport layer through a steel mesh (72/36) and dried by heating at 140° C. for 2 min.

Roll-to-Roll Manufacture of Devices—P3HT/PCBM Active Layer

For roll-to-roll coating experiments, PET foil (130 micron) with an electrode pattern of ITO (60-90 Ohm square⁻¹) was used as the substrate and transparent electrode. The ink for the electron transport layer (zinc oxide layer) was slot-die coated, with corona treatment prior to coating (500 W) (UV-ozone treatment for 5 min could also be used instead of corona treatment). A web speed of 2 m min⁻¹ was employed and the pumping rate adjusted such that a wet layer thickness of 3-4 micron was obtained. The drying temperature was 140° C. and the oven length was 1 metre. This gave a dry film that needed to be heat treated to become operational by passage through an oven 4 metre length at 0.2 m min⁻¹. This gave a total drying time of 0.5 minutes and a total curing time of 20 minutes.

The ink for the active layer (in this case, the P3HT/PCBM ink in chlorobenzene) was then slot-die coated using a R2R process on to the electron transport layer by slot-die coating. The resulting film was dried at 140° C. for 0.5 min using a 1 metre oven length and a web speed of 2 m min⁻¹.

The insoluble active layer was then wetted with isopropanol in order to ensure acceptable wetting of the layer with the ink for the hole transport layer, which was then slot-die coated on to the wetted active layer using a R2R machine at a web speed of 0.3 m min⁻¹. The PEDOT:PSS film was dried at 140° C. for 3 min. The silver electrode was then screen printed on to the hole transport layer using a steel mesh (72/36) and dried at 140° C. for 1.2 min using a web speed of 1 m min⁻¹ and an oven length of 1.2 m.

Full Roll-to-Roll Manufacture of Devices—Polymer 1/Fullerene Active Layer

For roll-to-roll coating experiments, PET foil (130 micron) with an electrode pattern of ITO (60-90 Ohm square⁻¹) was used as the substrate and transparent electrode. The ink for the electron transport layer was slot-die coated, with corona treatment prior to coating (500 W) (UV-ozone treatment for 5 min could also be used instead of corona treatment). A web speed of 2 m min⁻¹ was employed and the pumping rate was adjusted such that a wet layer thickness of 3-4 micron was obtained. The drying temperature was 140° C. and the oven length was 1 metre. This gave a dry film that needed to be heat treated to become operational by passage through an oven 4 metre length at 0.2 m min⁻¹. This gave a total drying time of 0.5 minutes and a total curing time of 20 minutes.

The ink for the active layer (in this case, polymer 1 and fullerene 2 or PCBM in aqueous solution) was then coated on to the electron transport layer by slot-die coating. The resulting film was thermocleaved at 140° C. at a speed of 0.1 m min⁻¹, or alternatively was passed twice through the oven at a speed of 0.2 m min⁻¹ (total heating time 40 min). This does not result in complete thermocleavage of polymer 1 to the carboxylic acid, but does make the active layer sufficiently insoluble for successful application of subsequent layers. However, this method does not lead to the best device performance, and ideally heating for at least 2 h at 140° C. would be used, which would require the use of a longer oven for a full roll-to-roll process.

The insoluble active layer was then wetted with isopropanol in order to ensure acceptable wetting of the layer with the ink for the hole transport layer, which was then slot-die coated on to the wetted active layer. The PEDOT:PSS film was dried at 140° C. for 5 min. The silver electrode was then screen printed on to the hole transport layer using a steel mesh (72/36) and dried at 140° C. for 2 min.

Partial Roll-to-Roll Manufacture of Devices—Polymer 1/Fullerene Active Layer

PET foil (130 micron) with an electrode pattern of ITO (60-90 Ohm square⁻¹) was used as the substrate and transparent electrode. The ink for the electron transport layer was slot-die coated, with corona treatment prior to coating (500 W) (UV-ozone treatment for 5 min could also be used instead of corona treatment). A web speed of 2 m min⁻¹ was employed and the pumping rate was adjusted such that a wet layer thickness of 3-4 micron was obtained. The drying temperature was 140° C. and the oven length was 1 metre. This gave a dry film that needed to be heat treated to become operational by passage through an oven 4 metre length at 0.2 m min⁻¹. This gave a total drying time of 0.5 minutes and a total curing time of 20 minutes.

The ink for the active layer (in this case, polymer 1 and fullerene 2 or PCBM in aqueous solution) was then coated on to the electron transport layer by slot-die coating. The web was cut into individual sheets each with a partially-formed solar cell module thereon. The sheets were thermocleaved in a static hot air oven at 140° C. for 2 h or 4 h. The 4 h heating time was preferred as this achieved full thermocleavage of the polymer precursor to the carboxylic acid. Subsequent steps were of course carried out on individual sheets.

The insoluble active layer was then wetted with isopropanol in order to ensure acceptable wetting of the layer with the ink for the hole transport layer, which was then slot-die coated on to the wetted active layer. The PEDOT:PSS film was dried at 140° C. for 5 min. The silver electrode was then screen printed on to the hole transport layer using a steel mesh (72/36) and dried at 140° C. for 2 min.

Device Performance

The performance for the all aqueous processed devices made on a laboratory scale were in the range of 0.6-1.1%.

For comparison, using the well known P3HT:PCBM materials combination a performance of 1.6-2% was obtained when processing the active layer (P3HT:PCBM) from chlorobenzene while using aqueous processing for all the other layers (ZnO, PEDOT:PSS and silver back electrode) i.e. according to the second procedure given in Example 9.

It was found that these devices gave excellent stability during storage and operation under ambient conditions when encapsulated using a simple food packaging barrier.

1. A method of preparing a coating ink for forming a zinc oxide electron transport layer, comprising mixing zinc acetate and a wetting agent in water or methanol.

2-43. (canceled)

44. The method of claim 1, wherein the zinc acetate is used in the form Zn(OAc)₂.2H₂O.

45. The method of claim 1, wherein the wetting agent is Zonyl® FSO-100 (2-(perfluoroalkyl)ethanol, CAS No 65545-80-4) or Triton® X-100 (polyethylene glycol p-(1,1,3,3-tetramethylbutyl)-phenyl ether, CAS No 9002-93-1).

46. The method of claim 1, wherein the method further comprises mixing AlOH(OAc)₂ into the zinc acetate and a wetting agent in water or methanol and subsequently filtering out solids.

47. A coating ink comprising zinc acetate and a wetting agent in aqueous solution or methanolic solution.

48. The coating ink of claim 47, wherein the zinc acetate is used in the form Zn(OAc)₂.2H₂O.

49. The coating ink of claim 47, wherein the wetting agent is Zonyl® FSO-100 (2-(perfluoroalkyl)ethanol, CAS No 65545-80-4) or Triton® X-100 (polyethylene glycol p-(1,1,3,3-tetramethylbutyl)-phenyl ether, CAS No 9002-93-1).

50. The coating ink of claim 47, wherein the coating ink further comprises AlOH(OAc)₂.

51. A method of preparing a zinc oxide electron transporting layer, comprising:
i) coating a substrate with a coating ink comprising zinc acetate and a wetting agent in aqueous solution or methanolic solution so as to form a film on said substrate;
ii) drying the film; and
iii) heating the dry film to convert the zinc acetate substantially to ZnO.

52. A method of preparing an organic photovoltaic device or an organic LED comprising a zinc oxide electron transport layer, the method comprising, in this order:
a) providing a substrate bearing a first electrode layer;
b) forming an electron transport layer according to the following method:
i) coating the substrate with a coating ink comprising zinc acetate and a wetting agent in aqueous solution or methanolic solution so as to form a film;
ii) drying the film; and
iii) heating the dry film such that the zinc acetate is substantially converted to ZnO;
c) forming an active layer;
d) forming a hole transport layer; and
e) forming a second electrode layer.

53. The method of claim 52, wherein step c) is carried out by applying a coating ink comprising a light-harvesting polymer and an electron acceptor to the electron transport layer, and drying the coating ink layer.

54. The method of claim 52, wherein step c) is carried out by applying a coating ink comprising a soluble precursor of a light harvesting polymer, an electron acceptor and a solvent to the electron transport layer, drying the coating ink layer, and treating the dried coating ink layer to convert the soluble precursor into a light harvesting polymer that is substantially insoluble in the solvent of the coating ink.

55. The method of claim 54, in which the coating ink in step c) comprises a precursor of a light harvesting polymer, a fullerene, THF, an alcohol and water.

56. The method of claim 52, wherein the hole transport layer is formed according to the following method:
i) coating the active layer with a solution of a hole conducting compound in water and/or an alcohol or mixture of alcohols so as to form a film; and
ii) drying the film to form a hole transport layer.

57. The method of claim 56, wherein the active layer is wetted with an alcohol prior to the coating step (i).

58. The method according to claim 52, wherein the electrode is a metal electrode.

59. The method according to claim 58, wherein the electrode is formed by coating an ink comprising metal flakes, water and a water-soluble binder on to the hole transport layer and drying said ink.

60. The method according to claim 58, wherein the metal electrode comprises silver.

61. An optoelectronic device comprising an electron transporting layer comprising zinc oxide and a wetting agent.

62. The optoelectronic device according to claim 61, in which the wetting agent is Zonyl® FSO-100 (2-(perfluoroalkyl)ethanol, CAS No 65545-80-4) or Triton® X-100 (polyethylene glycol p-(1,1,3,3-tetramethylbutyl)-phenyl ether, CAS No 9002-93-1).
